(19) United States
(12) Patent Application Publication
(10) Pub. No.: US 2009/0047793 A1
(43) Pub. Date: Feb. 19, 2009

(54) METHOD OF MANUFACTURING SEMICONDUCTOR DEVICE

(75) Inventor: Masanaga Fukasawa, Tokyo (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/190,351

(22) Filed: Aug. 12, 2008

(30) Foreign Application Priority Data
Aug. 14, 2007 (JP) 2007-211221

(51) Int. Cl. H01L 21/302

(52) U.S. Cl. 438/725; 257/E21.027

(57) ABSTRACT

Disclosed herein is a method of manufacturing a semiconductor device, including the step of ashing away by a plasma treatment an organic material film formed over a substrate with an inter-layer insulator film therebetween, wherein the plasma treatment is conducted while electric power applied so as to draw ions in a plasma toward the substrate is periodically turned ON and OFF.

### CROSS REFERENCES TO RELATED APPLICATIONS

The present invention contains subject matter related to Japanese Patent Application JP 2007-211221 filed in the Japan Patent Office on Aug. 14, 2007, the entire contents of which being incorporated herein by reference.

### BACKGROUND OF THE INVENTION

1. Field of the Invention

The present invention relates to a method of manufacturing a semiconductor device, particularly to a method of manufacturing a semiconductor device which includes the step of removing a resist present over a low dielectric constant film (hereinafter referred to also as low-k film).

2. Description of the Related Art

Attendant on the recent demand for semiconductor devices having higher operation speeds and finer structures, it has been requested to lower the wiring resistance and lower the dielectric constant of an inter-layer insulator film. To cope with the request, in the most advanced devices, it has become a general practice to use copper (Cu) wiring, which is low in resistance than aluminum (Al) alloy wiring used in the related art, and to use a low-k film having a lower dielectric constant as the inter-layer insulator film.

For forming the Cu wiring, a forming method different from that for the Al alloy wiring is adopted, in view of the difficulty in etching a Cu film. In the forming method newly adopted, a Cu film is formed so as to fill up grooves and contact holes preliminarily formed in the inter-layer insulator film, and thereafter the Cu film present on the inter-layer insulator film is polished by CMP (Chemical Mechanical Polishing) to leave the Cu film merely in the grooves and the contact holes, thereby forming the Cu wiring. The wiring obtained by such a method is generally called “embedded wiring”.

The most serious problem in forming the embedded wiring lies in that, when a low-k film is used as the inter-layer insulator film, a great damage to the low-k film is generated. Specifically, in the formation of the embedded wiring, grooves and contact holes are formed in the inter-layer insulator film by pattern etching conducted using a resist as a mask, and removing the resist by ashing after the pattern etching. In this case, an SiOCH film being an ordinary low-k film is used as the inter-layer insulator film, an oxygen plasma employed in the ashing treatment causes methyl groups (CH₃ groups) to be liberated from the exposed surface side of the SiOCH film, resulting in the formation of a damaged layer.

In order to prevent the generation of the damaged layer, a method has been proposed in which an ashing treatment using a nitrogen plasma or a hydrogen plasma is conducted for removing the resist present over the inter-layer insulator film which includes a low-k film. In such an ashing treatment, a modified layer is formed at side wall portions of the wiring grooves and contact holes, and the modified layer functions as a barrier for restraining ions and radicals from entering through the exposed surfaces into the low-k film, whereby formation of the damaged layer can be prevented from occurring (refer to, for example, Japanese Patent Laid-Open No. 2002-9050 (hereinafter referred to as Patent Document 1) and Japanese Patent Laid-Open No. 2004-103747 (hereinafter referred to as Patent Document 2)).

In addition, there has also been proposed a method in which anisotropic plasma ion ashing is conducted in a first step to form a modified layer at side wall portions (portions not irradiated with ions) of the wiring grooves and contact holes, and a plasma is generated by irradiating a process gas with microwaves in a second step to thereby apply microwave plasma ashing to the resist film at a high speed (refer to, for example, Patent Document 1).

Furthermore, a method has been proposed in which ashing is conducted while supplying an RF bias on a substrate, whereby ions in a plasma are drawn toward the substrate, thereby obtaining a sufficient ashing rate, and a denatured surface layer of a resist film is removed. In this case, it is said, it is possible by controlling the RF bias power to achieve a sufficient ashing rate, satisfactory performance of removing the denatured surface layer of the resist film, and prevention of degradation of the dielectric constant of the inter-layer insulator film. It is also said that in the case of a plasma rich in nitrogen (N), a denatured surface layer is formed at the surface of the low-k film, and the denatured surface layer functions as a barrier layer against diffusion of radicals, whereby further formation of the damaged layer in the low-k film is restrained (refer to Patent Document 2).

Thus, especially in the case of a nitrogen (N)-containing plasma (for example, in the case where H₂/N₂ or NH₃ is used as a process gas), at side walls where ion irradiation energy and ion flux (the number of ions per unit time) are low, a modified layer (protective film) containing N at least is formed, and it is possible by the protective film to restrain the formation of side wall damaged layers (the layers causing a rise in relative permittivity). On the other hand, the reaction layer at the resist surface irradiated with ions is immediately removed by the ions, so that ashing progresses. Accordingly, it is possible to achieve ashing for removing the resist while restraining the formation of the damaged layer at the side walls.

### SUMMARY OF THE INVENTION

However, the ashing treatment by use of a plasma rich in nitrogen (N) as above-mentioned has the problem that a further lowering in the dielectric constant of the inter-layer insulator film needs a thicker modified layer (protective film) on the side walls, i.e., the modified layer at the side walls has to be thicker. This may lead to the need for a lowering in ion energy. As the ion energy is lowered, however, the protective film is formed gradually and thinly on the resist as well as formed on the side walls of the low-k film, whereby the ashing rate is lowered extremely. Further, the resist may not be completely removed, i.e., resist residue would be generated, making the device unsuitable for practical use. On the other hand, if the ion energy is elevated in order to solve this problem, the modified layer (protective film) at the side walls becomes thinner, and its protective effect is lost, so that more damaged layer would be formed at the side walls. Therefore, there is a keen demand for a technology by which an enhanced energy for preventing the generation of resist residue can be realized while securing a lowered energy for forming the protective film for restraining the formation of the damaged layer and while securing a desired ashing rate.

Accordingly, there is a need for a method of manufacturing a semiconductor device by which an organic material film such as resist can be ashed away without causing degradation of the film quality of an inter-layer insulator film beneath the organic material film.

In accordance with an embodiment of the present invention, there is provided a method of manufacturing a semiconductor device, including the step of ashing away by a plasma treatment an organic material film formed over a substrate with an inter-layer insulator film therebetween, wherein the plasma treatment is conducted while electric power applied so as to draw ions in a plasma toward the substrate is periodically turned ON and OFF, i.e., while so-called time modulation (TM) biasing is performed.

In such a method, when the electric power applied to the substrate 101 is turned OFF as shown in FIG. 1B, the energy of incident ions becomes extremely low. As a result, a thick modified layer a as a protective film is formed on side walls. During this period, however, the protective layer would be formed also on the resist, so that removal of the resist does not proceed effectively. On the other hand, when the power applied to the substrate 101 is turned OFF as shown in FIG. 1A, ions at high energy are supplied from the plasma p onto the substrate 101. As a result, ashing of the resist proceeds effectively. In addition, etching of the modified layer a on the side walls is also progressed upon turning-ON of the electric power applied to the substrate 101.

Thus, in the embodiment of the present invention, when the electric power is OFF, a thick modified layer a is formed on the side walls, and is used as a damage protecting layer. On the other hand, when the power is ON, ashing of the resist is effected while protecting the modified layer a at the side walls of the low-k film. With these stages repeated alternately, the modified layer a to be a protective film for the low-k film can be formed in a large thickness without lowering the ashing rate, and, consequently, the damage to the low-k film can be reduced. While the electric power applied to the substrate 101 is ON, the modified layer a at the side walls is also thinned, but by turning OFF the power before the modified layer a is completely lost, a thick modified layer a can be formed steadily.

According to the embodiment of the present invention, the resist can be ashed away while maintaining a sufficient ashing rate for mass production and while preventing the formation of a damaged layer by using a modified layer as a barrier, so that deterioration of film quality of the inter-layer insulator film due to a damaged layer can be obviated. Consequently, it is possible, for example, to maintain a low dielectric constant of the inter-layer insulator film, to prevent wiring provided adjacently to the inter-layer insulator film from being deteriorated due to absorption of moisture into a damaged layer, and to enhance the reliability of a semiconductor device manufactured by using this inter-layer insulator film.

### BRIEF DESCRIPTION OF THE DRAWINGS

FIGS. 1A and 1B are sectional step views for illustrating the embodiment of the present invention;

FIGS. 2A to 2C are sectional step views (No. 1) for illustrating an embodiment of the present invention;

FIGS. 3A to 3C are sectional step views (No. 2) for illustrating the embodiment of the present invention; and

FIG. 4 is a diagram illustrating a pulse wave at the time of an ashing treatment.

### DETAILED DESCRIPTION OF THE PREFERRED EMBODIMENT

Now, an embodiment of the present invention will be described in detail below, based on the drawings.

### First Embodiment

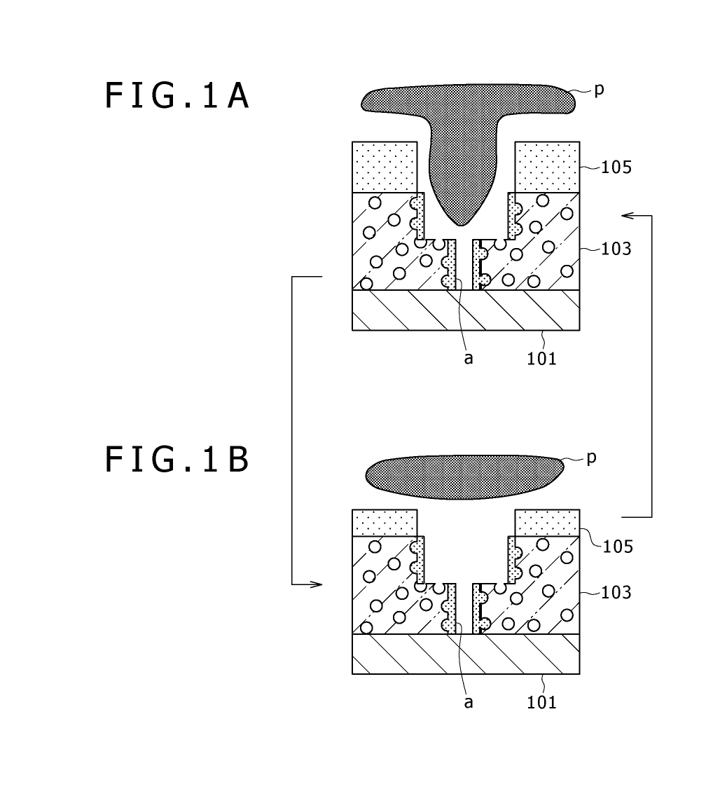

FIGS. 1A and 1B are sectional step views for illustrating a first embodiment of the present invention. The first embodiment will be described based on these views.

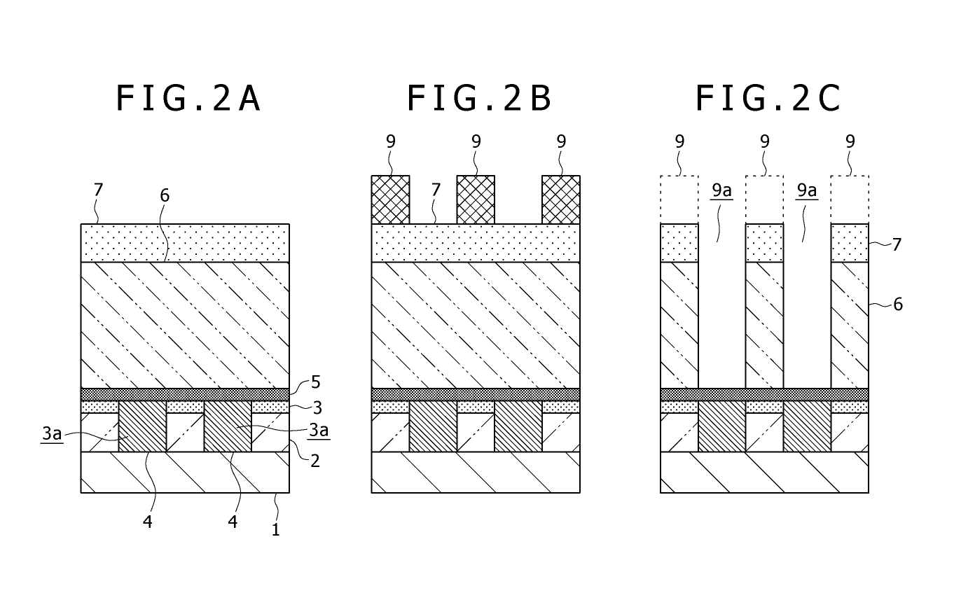

First, as shown in FIG. 2A, a substrate 1 in which a semiconductor substrate provided with semiconductor devices such as MOS transistors is covered with an under insulator film is prepared. A carbon-containing silicon oxide (SiOC) film 2 and a silicon oxide film 3 are sequentially formed over the substrate 1 in this order, wiring grooves 3a are formed in the SiOC film 2 and the silicon oxide film 3, and thereafter the wiring grooves 3a are filled up with a first Cu wiring 4.

Next, a Cu diffusion preventing film 5 including a silicon carbide [SiC (N, H)] film is formed on the silicon oxide film 3 in the state of covering the first Cu wiring 4. Thereafter, an inter-layer insulator film 6 as the so-called low-k film having a dielectric constant (k) lower than that of silicon oxide (dielectric constant k=4.0) is formed over the Cu diffusion preventing film 5. Here, for example, an inter-layer insulator film 6 including a porous SiCOH film is formed. The low-k inter-layer insulator film 6 is not limited to the porous SiCOH film, and it suffices to use an inorganic material film containing silicon (Si), oxygen (O), carbon (C) and hydrogen (H) or an organic low-k film containing C, H and O.

Then, a hard mask layer 7 including silicon oxide (SiO₂) is formed on the low-k inter-layer insulator film 6.

Next, as shown in FIG. 2B, a resist pattern 9 for contact holes is formed on the hard mask layer 7 by a lithographic treatment.

Subsequently, as shown in FIG. 2C, the hard mask layer 7 is etched by using the resist pattern 9 as a mask; further, using the thus etched hard mask layer 7 as a mask, the inter-layer insulator film 6 is etched, to form contact holes 9a. Incidentally, the resist pattern 9 is removed by the etching of the hard mask layer 7 and the inter-layer insulator film 6.

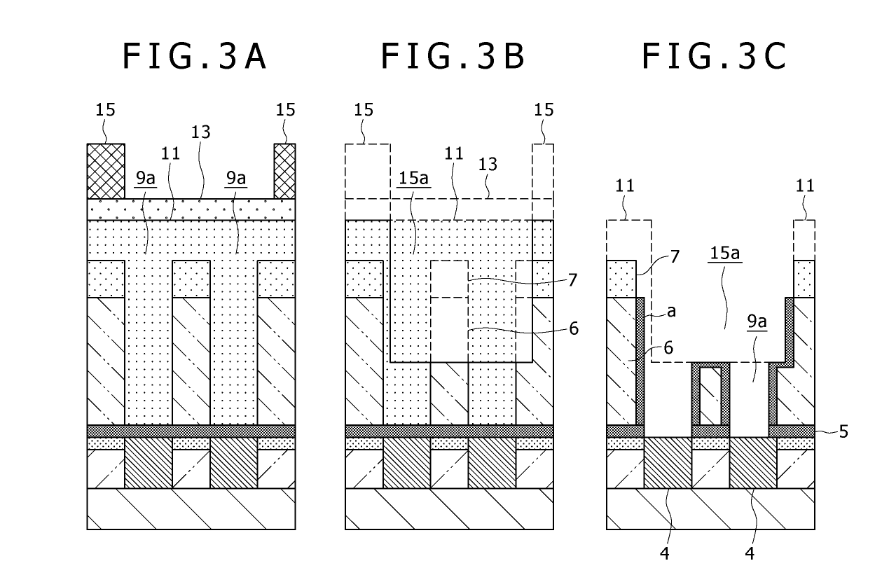

Next, as shown in FIG. 3A, an organic material film 11 is formed in the state of filling up the contact holes 9a, and, further, a silicon oxide film 13 is formed thereon. Thereafter, a resist pattern 15 for wiring grooves is formed on the silicon oxide film 13 by a lithographic treatment.

Subsequently, as shown in FIG. 3B, the silicon oxide film 13, the organic material film 11, the hard mask layer 7 composed of the silicon oxide film, and an upper part of the low-k inter-layer insulator film 6 composed of the porous SiCOH film are etched using the resist pattern 15 as a mask, to form wiring grooves 15a. Incidentally, the resist pattern 15 and the silicon oxide film 13 are removed by this etching.

Thereafter, the organic material film 11 embedded in (filling up) the contact holes 9a or left on the substrate 1 is ashed away by a plasma treatment. In this case, as has been described referring to FIG. 1 above, time modulation (TM) biasing is conducted, i.e., electric power applied so as to draw the ions in the plasma toward the substrate is turned ON/OFF periodically.

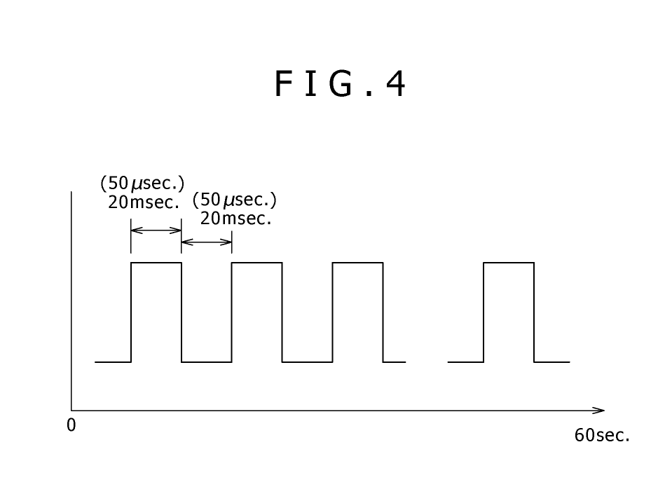

In the TM biasing, it suffices that the RF bias applied to the substrate is applied as a pulse wave according to the frequency, as shown in FIG. 4. Specifically, in a plasma treatment in ordinary ashing-away, an RF bias at a frequency of 800 kHz to 60 MHz is applied to the substrate. In the case of applying an RF bias as a TM bias, for example, in the case of an RF bias at a frequency of 800 kHz, a 1:1 duty ratio of about 20 ms:20 ms (ON duration/OFF duration) is adopted. On the other hand, for example in the case of a high-frequency RF bias at a frequency of 60 MHz, a 1:1 duty ratio of about 50 μs:50 μs with the ON and OFF durations further shortened is adopted. Incidentally, the ON/OFF duty ratio is not limited to 1:1. Besides, the overall treatment time does not depend on the frequency of the RF bias, and may be an equal or comparable time according to the material and thickness of the organic material film 11 to be removed.

Here, a plasma treatment using a nitrogen (N₂) gas and a hydrogen (H₂) gas as a process gas is performed. An exemplary set of treatment conditions are as follows.
Apparatus: Parallel flat plate type etching apparatus
Gap interval: 40 mm
Source power: 1000 W
RF bias: 800 kHz
RF bias power: 100 W (TM bias duty ratio=20 ms:20 ms)
Process gas: H₂/N₂=100/100 sccm
Pressure: 30 mTorr
Substrate temp.: 20° C.
Treatment time: 60 sec

After the organic material film 11 is ashed away as above, the step of removing the Cu diffusion preventing film 5 including the silicon carbide [SiC (N, H)] film present at bottom portions of the contact holes 9a is conducted, whereby the first Cu wiring 4 is exposed at the bottom portions of the contact holes 9a.

Thereafter, if necessary, a damage recovering treatment for compensating for the methyl groups (CH₃ groups) liberated from the exposed surface layer of the inter-layer insulator film 6 by the plasma treatment is conducted. Where a plasma treatment including applying an RF bias to the substrate is conducted as the damage recovering treatment, the RF bias may be a TM bias in the same manner as above.

Thereafter, an embedded wiring in which the wiring grooves 15a and the contact holes 9a provided in bottom surfaces thereof are filled up with a Cu film is formed, though not shown in the figures. This step may be conducted in the same manner as in the related art. Specifically, a barrier metal film of tantalum (Ta) for preventing diffusion of Cu is formed in the state of covering the inside walls of the wiring grooves 15a and the contact holes 9a, and a Cu film in such a thickness as to sufficiently fill up the wiring grooves 15a and the contact holes 9a through the barrier metal film therebetween is formed. Thereafter, the excess Cu film and barrier metal film present on the inter-layer insulator film 6 are removed by CMP polishing, to form the embedded wiring in which merely the wiring grooves 15a and the contact holes 9a are filled up with the Cu film through the barrier metal layer therebetween.

According to the manufacturing method as above-described, as shown in FIG. 3C, when the organic material film 11 on the inter-layer insulator film 6 composed of the porous SiCOH film provided with the wiring grooves 15a and the contact holes 9a is ashed away by a plasma treatment, the RF bias applied to the substrate 1 is turned ON/OFF in a pulsed manner, i.e., TM biasing is carried out.

This ensures that during the plasma treatment, anisotropic ashing with the ions drawn to the side of the substrate 1 is conducted when the electric power applied to the substrate 1 is ON. This ashing ensures that ashing-away of the organic material film 11 is progressed while forming a modified layer a at the exposed side walls of the inter-layer insulator film 6. In this case, since the N₂ gas is used as the process gas in the plasma treatment, the modified layer a is a CNx deposited film or a nitrogen (N)-rich layer (N-rich layer: for example, Si, O, C, N, H), that is, a deposited film with a high N content.

On the other hand, when the electric power applied to the substrate 1 is OFF, drawing of the ions toward the substrate 1 is stopped, so that ashing of the organic material layer 11 is progressed while the modified layer a formed beforehand on the exposed side walls of the inter-layer insulator film 6 is being removed by isotropic etching. Consequently, the removal of the organic material film 11 by ashing is progressed without leaving an excessively thick modified layer a and while protecting the side walls of the inter-layer insulator film 6 by the modified layer a to thereby prevent the formation of a damaged layer.

Thus, in the plasma treatment shown in FIG. 3C, the removal of the organic material film 11 by ashing can be achieved without leaving an excessively thick modified layer a on the side walls of the inter-layer insulator film 6 and while preventing the formation of a damaged layer at the exposed side walls of the inter-layer insulator film 6 through the function of the modified layer a as a barrier. Therefore, the film quality of the inter-layer insulator film 6 can be prevented from being degraded due to formation of a damage layer or due to leaving of the modified layer a. This makes it possible to keep low the dielectric constant of the inter-layer insulator film 6 formed by use of a porous SiCOH film, to prevent the embedded wiring provided adjacently to the inter-layer insulator film 6 from being deteriorated due to absorption of moisture into a damaged layer, and to enhance the reliability of a semiconductor device fabricated by use of the inter-layer insulator film 6.

In addition, when the RF bias to be applied to the substrate 1 is turned ON and OFF in a pulsed manner as a TM bias, the incidence energy of ions during ON time (the power applied to the substrate) can be made higher than that in the case of using a continuous wave form bias. When high-energy ions are incident on the substrate, a hardened layer having a very high density is formed at the bottoms of the wiring. As a result, the hardened layer serves as a protective film to suppress further damage to the wiring bottoms, which also contributes to the reduction of the damage (wiring bottoms) given to the inter-layer insulator film 6 due to collision of ions. Therefore, the damage to the wiring side walls is restrained by the modified layer a (formed during OFF time) consisting at least of an N-rich layer and serving as a damage-restraining layer, whereas the damage to the wiring bottoms is restrained by the high-density layer (formed during ON time) formed by irradiation with ions. These make it possible to simultaneously realize suppression of damage to the wiring side walls and suppression of damage to the wiring bottoms.

Incidentally, as a comparative example, removal of the organic material film 11 by ashing was conducted by a plasma treatment under the same ashing conditions as above, except that the RF bias was changed to a continuous wave form bias. In the semiconductor device obtained in this manner, the thick modified layer and the damaged inter-layer insulator film were liable to absorb moisture, and the attendant rise in relative permittivity caused increases in capacity between embedded wiring portions and capacity between layers. Further, when a heat treatment was conducted after forming the barrier metal film (Ta) for the Cu film in the embedded wiring, oxidation of the barrier metal film (Ta) was brought about by water arising from the absorption of moisture into the inter-layer insulating film, leading to degradation of reliability of the embedded wiring and to failure or defect in the semiconductor device.

In the embodiment above, description has been made of the case of using a nitrogen gas (N₂) and a hydrogen gas (H₂) as the process gas in the plasma treatment for ashing away the organic material film 11. However, other gases can also be used as the process gas in the plasma treatment for ashing, and a modified layer a differing dependant on the gas(s) used is formed. Examples of the gas which can be used as the process gas in the plasma treatment for the ashing include an oxygen gas (O₂) as well as a helium gas (He) and an argon gas (Ar) serving as carrier gas. Further, an NH₃ gas can also be used effectively.

For example, when a plasma treatment using an oxygen gas (O₂) as the process gas is carried out, the treatment conditions may be as follows.
Apparatus: Parallel flat plate type etching apparatus
Gap interval: 40 mm
Source power: 1000 W
RF bias: 800 kHz
RF bias power: 100 W (TM bias duty ratio=10 ms:30 ms)
Process gas: O₂=300 sccm
Pressure: 20 mTorr
Substrate temp.: 0° C.
Treatment time: 70 sec

By such a plasma treatment, also, the ashing of the organic material film 11 can be progressed while the side walls of the inter-layer insulator film 6 are protected by the modified layer a to thereby prevent the formation of a damaged layer. Particularly, in the case of a plasma using the O₂ gas, the effect at the side walls is lower than that in the case of the H₂/N₂ gas. This is due to the fact that the protective film is little formed on the side walls. However, in the case of the TM bias, the incident ion energy during ON time can be set to be higher, as compared to the case of a continuous wave bias. Therefore, in the case of the wiring bottoms where the influence of the ion irradiation is great, a high-density layer is formed in a short time, and the damaging thereafter is restrained. Therefore, in the case of a plasma containing the O₂ gas, particularly in the case of damage to the wiring bottoms, the embodiment of the present invention is very effective. On the damage to the side walls, the suppressing effect of the embodiment of the present invention is slight.

In the embodiment above, description of the present invention has been made by exemplifying the step in which the organic material film 11 on the inter-layer insulator film 6 composed of the porous SiCOH film provided with the wiring grooves 15a and the contact holes 9a is ashed away by a plasma treatment, as shown in FIG. 3C. However, this technique can also be used in the step in which, after the ashing for removing the resist (FIG. 3C), the damage formed by the ashing is covered from above in order to suppress the influence of the damage.

Specifically, as an after-step of the plasma treatment after the removal of the organic material film 105 by ashing, so-called poly-sealing process is conducted in which a modified layer a is formed on the exposed side walls of the inter-layer insulator film 103. In the poly-sealing process, a plasma treatment may be conducted in which the RF bias to be applied to the substrate 1 is turned ON/OFF in a pulsed manner as a TM bias.

In addition, the removal of the organic material film by the above-mentioned time modulation (TM) biasing may be applied to the resist pattern 15 left unremoved upon the step of FIG. 3B.

It should be understood by those skilled in the art that various modifications, combinations, sub-combinations and alterations may occur depending on design requirements and other factor in so far as they are within the scope of the appended claims or the equivalents thereof.

What is claimed is:

1. A method of manufacturing a semiconductor device, comprising the step of:
ashing away by a plasma treatment an organic material film formed over a substrate with an inter-layer insulator film,
wherein said plasma treatment is conducted while electric power applied so as to draw ions in a plasma toward said substrate is periodically turned ON and OFF.

2. The method of manufacturing the semiconductor device as set forth in claim 1,
wherein said plasma treatment is conducted by use of a nitrogen-containing gas as a process gas.

3. The method of manufacturing the semiconductor device as set forth in claim 1,
wherein said inter-layer insulator film includes an inorganic material film having a dielectric constant lower than that of silicon oxide.

4. The method of manufacturing the semiconductor device as set forth in claim 1,
wherein said plasma treatment is conducted while forming a modified layer on an exposed side wall.

5. The method of manufacturing the semiconductor device as set forth in claim 1,
wherein said plasma treatment is conducted in such a manner that formation of a modified layer on a side wall is conducted when said voltage applied is OFF, whereas said ashing of said organic material film is conducted while protecting said side wall with said modified layer when said voltage applied is ON.
